(19) United States
(12) Patent Application Publication
(10) Pub. No.: US 2010/0003456 A1
(43) Pub. Date: Jan. 7, 2010

(54) COATED BODY AND METHOD FOR ITS PRODUCTION

(75) Inventor: Joachim Gussone, Koln (DE)

Correspondence Address: BANNER & WITCOFF, LTD., 1100 13th STREET, N.W., SUITE 1200, WASHINGTON, DC, 20005-4051, US

(73) Assignee: CEMECON AG, Wurselen (DE)

(21) Appl. No.: 12/303,203

(22) PCT Filed: Jun. 1, 2007
(86) PCT No.: PCT/EP2007/004859

§ 371 Date: May 11, 2009

(30) Foreign Application Priority Data
Jun. 2, 2006 (DE) 10 2006 026 253.0

(51) Int. Cl. B32B 5/16; B05D 3/10; C23C 16/00

(52) U.S. Cl. 428/138; 427/309; 427/122

(57) ABSTRACT

A description is given of a coated body and a method for producing and coating a body. The body has a substrate of a hard metal or cermet, comprising hard material particles (1) and binder material (2) and an adhering diamond layer (4) provided on top. At least some of the hard material particles (1) on the surface of the substrate and under the diamond layer (4) have transcrystalline depressions in the form of holes. The substrate may consist of hard metal, preferably consisting of WC and Co. A CVD diamond layer may be applied to the functional surfaces. In the case of at least one of the diamond-coated functional surfaces, the cobalt content of the surface, specified in % by weight, in relation to the WC, measured by means of energy-dispersive X-ray fluorescence, is only reduced by a maximum of 50% in comparison with the untreated substrate. In the method according to the invention, hard material particles on the surface of the substrate are subjected to transcrystalline corrosion by chemical etching in such a way that depressions are created in the form of pits or holes.

The invention relates to a coated body and a method for coating a body.

Providing bodies or parts of bodies with a surface coating for improving the mechanical properties is well known. In particular for tools, providing functional surfaces with a diamond layer is well known. A well known method consists in applying a diamond layer by means of a CVD (chemical vapor deposition) process. Such a coating method is described, for example, in WO 98/35071.

Coated bodies comprise a substrate material and a diamond layer applied thereon. In the context of the present invention, hard metals and cermets, i.e. sintered materials comprising hard material particles and binder material, in particular with WC particles in a Co-containing matrix, will be regarded as the substrate material. Diamond coated hard metal or cermet tools are used in machining, amongst others. There, particularly the great hardness of diamond positively affects the wear protection of the tool.

To ensure good adhesion of the diamond coating on the substrate, various pretreating methods are known.

A common feature of the methods is that the binder of the substrate, in particular cobalt, is removed from the surface. Long processing times and high temperatures in CVD diamond coating processes lead to deleterious interactions between the carbon, which is to form the diamond layer, and the cobalt. The latter prevents diamond formation and results in graphitic phases instead. Removal was initially only effected by simple etching away of the cobalt with acids. It is however, part of the more recent prior art to use methods which remove other portions of the matrix as well as the cobalt and which change the structure of the surface.

Intermediate layers which are for preventing direct contact between cobalt and diamond, are also described, but have not reached any economical importance and are therefore not a subject matter.

For applying a diamond layer on a hard metal substrate, DE 19522372 initially proposes a Co-selective etching step with subsequent cleaning of the etched substrate surface, and then a WC-selective etching step with subsequent cleaning. In the WC etching step, only the removal of the WC particles damaged, in particular by grinding, is mentioned. Thereafter it is indicated, that well-defined WC particles are visible. A diamond layer is applied to the thus prepared hard metal substrate by means of a CVD method.

It should be noted with reference to the above mentioned references that two-step pretreating methods at first with a Co-selective etching step and then with a WC-selective etching step do not achieve sufficient layer adhesion in many cases. This is because if in the second, WC-selective etching step, complete etching is carried out of the WC particles at the surface, the surface subsequently comprises a Co enrichment which prevents good layer adhesion. If, however, WC etching is only partially carried out, the WC grains are etched on the grain boundaries at the surface, i.e. in the later transition area between the substrate and the diamond layer. This means, however, that there is no intact WC lattice, which leads to a reduction of layer adhesion and mechanical strength.

WO 97/07264 describes a pretreatment method for the CVD diamond coating of a hard metal. Herein, in a first step, electrochemical polishing of the hard metal is carried out, wherein the substrate is connected as an anode in an alkaline electrolyte (e.g. 10% NaOH) and electrochemically etched. In a second step, the Co binder material is selectively etched. Finally a diamond layer is applied in a CVD method.

The results achieved with this or with comparable two-step pretreatment methods, comprising initial WC etching and then Co etching, have shown acceptable layer adhesion for some applications. The strength achieved with this pretreatment does not suffice, however, for strong stresses, in particular shearing stresses and dynamic pressure stresses.

WO 2004/031437 describes a body and an associated method, wherein a porous, binder-free transition zone is arranged above an intact substrate material. The method can lead to good adhesion, in particular with very fine grain types, since the achieved surface roughness is independent of the carbide particle size.

In U.S. Pat. No. 6,110,240 and EP 9848077, a defined roughness is adjusted. This is also achieved by means of an electrochemical method, wherein a solution of alkali-chlorides is used. The desired roughness is primarily adjusted by means of added carbides and mixed carbides, which have a different etching rate than the primarily present tungsten carbide. The achievable roughnesses and the effective surface available for adhesion are here dependent on the original matrix structure.

U.S. Pat. No. 5,236,740 describes a method for coating a cobalt-sintered tungsten carbide substrate with a diamond film. It comprises a purely chemical method wherein tungsten carbide is first removed from the surface and subsequently a smaller amount of the binder using special chemicals. In the reference, substrates are used which are neither polished nor roughened, nor seeded in any way (with nucleation centers). In comparison with today's prior art, adhesion is limited or can only be achieved on certain substrates.

In summary it can be stated that in the prior art, etching methods are described, wherein structure portions are selectively removed by means of various etching solutions, sometimes in varying succession. Generally, acid etching is carried out, wherein the binder phase, in particular cobalt, is selectively removed from between the hard material particles, in particular the WC grains. It is part of the more recent prior art to use combinations with further etching stages, in which the hard material particles, or a particular type of hard material particles, are also selectively removed. In part of the publications the roughness of the surface is intentionally increased, which results in better adhesion between the layer and the CVD diamond. It should be pointed out, however, that excessive increase in roughness is problematic in some applications. The hard material particles are either completely removed or reduced in their circumference to such an extent that they fall out of the composite material. Since the binder is unsuitable as an adhesion base for diamond, the contact surface for the diamond primarily relies on the roughness of the surface and the given structure of the hard materials. The contact surface can only be enhanced to a certain extent, however, by increasing the overall roughness of the substrate surface.

It is an object of the invention to provide a coated body and a coating method with a previously carried out pretreatment therefor, wherein the body has increased stress resistance to various mechanical stresses.

This object is achieved by a body according to claim 1 and/or 11 and by a method according to claim 21. The dependent claims refer to advantageous embodiments of the invention.

In the first approach according to claim 1, according to the present invention, a special condition is suggested for the transition area between the substrate material (hard metal or cermet) and the diamond layer. The hard metal or cermet consists of hard material particles bound by a binder material, also referred to as a binder matrix.

In the prior art, the various components of the matrix are selectively removed. Under the present conditions, the etching attack is intercrystalline, i.e. it starts from the grain boundaries and results in a surface removal of the phases, which happens approximately parallel to the surface of the grain. The intercrystalline attack is the usual one under normal conditions.

In the approach according to the present invention, however, a body is described, wherein the hard material particles are etched in a transcrystalline manner, so that the subsequently applied CVD diamond layer adheres particularly well. The term “transcrystalline” refers to an etching attack wherein the material removal is carried out in an inhomogeneous manner into the interior of the grain. This effect is preferably so strong that it can also be referred to as pitting or hole corrosion.

In the method according to the present invention, which will be described in more detail below, this effect is intentionally utilized. The hole corrosion is usually undesirable in this field of technology. Pitting preferably begins at unavoidable defects on the hard materials and is self-reinforcing under the predetermined conditions. The hard material particles, in particular the carbides, are etched in such a manner that transcrystalline recesses in the form of holes or etched depressions result in the hard material particles.

In extreme cases, the holes can fully penetrate through the hard materials resulting in channels extending all the way through the particles.

In the method used, of course, only the hard material particles forming the surface of the substrate are affected by etching. And it is only these which are crucial for binding and adhering the diamond. Also, the recesses are often on the side of the hard material facing the diamond layer. If the hard material is already partially exposed on the side during the method according to the present invention or due to previous binder etching, again, recesses may result.

Compared to the methods mentioned in the prior art, the removal of binder and hard material can be kept small here. This weakens the substrate surface to a lesser extent. Also, it can be ensured that the roughness of the substrate surface does not increase, or only very little, and still a large surface is available for bonding with the diamond layer.

The pretreatment of the substrate can achieve a result wherein only the recesses are formed, but wherein the maximum diameter of the hard materials is not reduced so that the substrate is maintained in its outer contour. On the other hand, methods can also be used which additionally remove the hard materials in their entirety. This can be carried out, for example, by a previous etching step, which removes the hard materials on the surface. This can result, for example, in changes in diameter or in edge sharpness.

Further, the cohesion of the hard material, if any, is maintained. In the case of carbides, the compound of hard materials is also referred to as a carbide skeleton. In the carbide skeleton, the carbides touch, and an adhesive bonding at the points of contact can come about through the sintering process. If, as in the prior art, the carbides are etched on the surface, this bond is released.

The portions of the hard materials etched in a transcrystalline manner are completely free of binder or mixed phases still containing binder, so that excellent adhesion of the diamond is ensured on these surfaces.

Due to the recesses in the hard material particles according to the present invention, the diamond layer may be better anchored on the carbides, so that an additional improvement in adhesion is achieved by mechanical gripping. This gripping is very effective since the diamond can grow in and between the hard material grains. This results in numerous interlacings and undercuts.

In particular, the surface available for adhesion can be enlarged. Since transcrystalline etching can be extended almost at will, it can easily result in a multiplication of the surface, which is also not primarily dependent on the original matrix structure.

The high pressure stresses known to the person skilled in the art, which arise with CVD diamond coating due to the different coefficients of expansion of the layer and the substrate at the interface and within the layer, are directionally deflected by the changing contact surfaces in the interface. Shearing forces due to these stresses and the stress in operation can thus be better received and dissipated. Since diamond forms seeds for nucleation preferably at corners and edges, the higher number of contact points and the thus created grain structures result in additionally improved adhesion.

If additional nucleation points are created for the diamond by mechanical application of diamond powder, the crystals of the diamond powder can be particularly well anchored as seeds in the structure according to the present invention.

To achieve the desired improvement in adhesion, not necessarily all hard material particles of the surface need to have the recesses according to the present invention. A percentage of the hard material particles having the transcrystalline recesses of as little as 10% achieves improved adhesion. Preferably the percentage is at least 25%, particularly preferably at least 50%.

The percentage of affected hard material particles and the size and structure of the recesses may be determined on the uncoated substrate with the help of images recorded by means of an SEM (scanning electron microscope). This is not always feasible on a coated body; even a thin diamond layer would level the minute recesses. In this case, metallographic preparation is necessary, which removes the layer as far as the interface, to determine the percentage of hard material particles with recesses. Apart from the conventional mechanical methods, modern methods, such as ion etching would also be possible, in particular by means of FIB (Focused Ion Beam).

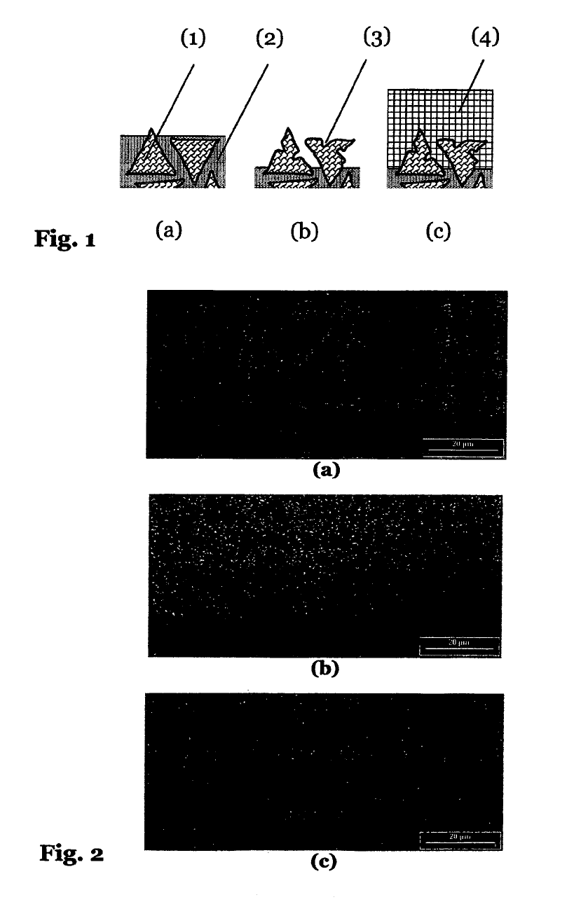

Metallographic preparation leads to underestimation of the number of recesses or holes, since here thus a 3-dimensional structure is projected on a 2-dimensional one, in particular when the interface is rough and only a portion of the hard material particles forming the surface is visible. The same applies if a metallographic transverse section is carried out in analogy to the diagram of FIG. 1 (c). This would lead to an even smaller number of visible recesses or holes. These methods thus only result in a lower limit for the above mentioned percentage. The number can be detected more precisely, however, by means of statistical methods, since the hard material particles are statistically equally distributed. A further, more complex approach would consist of photographing the transverse section from above through the diamond layer from different heights thus documenting the 3-dimensional structure in a plurality of 2-dimensional sections. This is particularly well achieved by the above mentioned FIB method, since the ion beam source may be integrated in a scanning electron microscope.

Further methods are the etching away of the substrate and evaluating the negative image of the substrate surface formed by the diamond layer; and, in the inverse case, etching away the diamond layer.

To achieve good gripping of the diamond layer on the hard material particles, a certain depth of the recesses is advantageous. Herein, the depth can be defined on the one hand as a function of the size of the hard material particles. Thus good gripping can be achieved, for example, if the mean depth of the recesses relative to the mean diameter of the hard material particles is at least 0.1, preferably at least 0.2, particularly preferably at least 0.3. In addition, the form of the recesses is also relevant, in particular, the ratio of the mean depth of the recesses to the mean diameter of the recesses. At a ratio of at least 0.5, for example, excellent gripping is the result. Further preferably the ratio is at least 1.0, particularly preferably at least 1.5. All numbers mentioned in the present document are always understood to refer to mean values.

To determine the depth of the recesses on the coated body, the same methods may be applied as in the determination of the percentage of the hard material particles affected by the recesses. In metallographic preparation by means of conventional grinding or by means of FIB, sections vertical to the interface or the layer provide more precise results, since the longitudinal axes of the recesses are mostly parallel to this section plane (see diagram in FIG. 1).

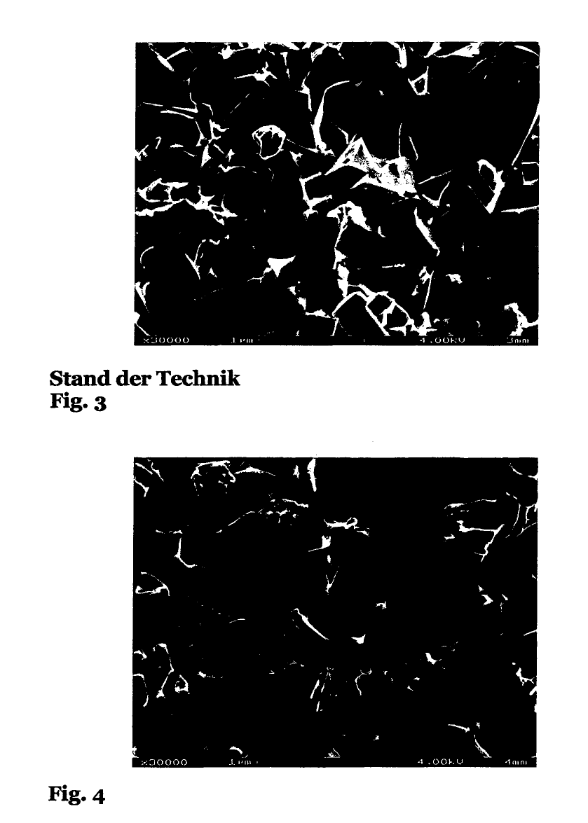

An alternative criterion for evaluating the effect according to the present invention is the surface percentage of the recesses created on the substrate surface. This is suitable in particular, when the hard materials are only discernible with difficulty, as is the case with ground or polished substrate surfaces or in cases where the recesses are less pertinent. The percentage of the substrate surface taken up by the recesses can be at least 1%, for example. A percentage as little as this can already result in improved adhesion compared with conventional pretreatments. Preferably the percentage is at least 5%, particularly preferably at least 10%. The surface percentages should relate to the parallel projection of the recesses onto an observation plane parallel to the substrate surface. This plane is also parallel to the diamond layer and further corresponds to the imaging plane of SEM images, when the scanning electron beam impinges vertically on the substrate surface, as is the case with the SEM images in FIGS. 3 and 4.

The grain diameter of the hard materials forming the surface of the substrate is not or only slightly reduced in most embodiments, however, changes in the contours can result due to the transcrystalline etching, and cavities can result between the carbides. It may be advantageous, under certain circumstances, to reduce the diameter of the hard materials even further, to increase these cavities. Overall, the surface of the substrate is further increased thereby. In addition, the pitting can thus better attack the surfaces of the hard material on the sides not facing the surface. The additional reduction of the grain diameter is advantageous, in particular, when there is only a small number of recesses, for example, or when the percentage of the particles affected by the recesses according to the present invention is relatively small.

The substrate materials contemplated in the context of the present invention are hard metals or cermets with sintered hard material particles and binder material. Binder materials can be, for example, Co, Ni, Fe, hard materials can be, for example, WC, TiC, TaC, NbC. The binder is about 6-25% by weight in the commercially used hard metals and cermets; in exceptions it is also 2-30% by weight.

Because of the hazardous nature of the binder, in the prior art, substrates having a low percentage of binder of up to 6% by weight, were used from the start for CVD diamond coating. The binder percentage was then further reduced in the surface. In improved pretreatments, such as in the one according to the present invention, good results can be achieved also with much higher binder percentages of more than 6%, such as with 7% binder and more, for example, with up to 20% by weight binder, preferably up to 12% by weight.

The substrate material used for the body and method according to the present invention is a sintered hard metal with WC hard material particles and a Co-containing binder material. Apart from Co and WC, the substrate only preferably contains few other elements and compounds, such as chromium and vanadium carbides, which were added for grain refining during sintering. These additional elements are present, however, preferably in an amount of less than 30 weight %, more preferably less than 5 weight %, even more preferably less than 2 weight %.

High cobalt percentages and small grain sizes improve the toughness of the hard metal. According to the present invention, however, all grain sizes of the hard material particles are suitable. These include the coarse (grain size 2.5-6 μm), medium (grain size 1.3-2.5 μm), fine (0.8-1.3 μm), extra fine (0.5-0.8 μm grain size) and ultra fine grain varieties (grain size 0.2-0.5 μm). Extra fine and ultra fine grain varieties are characterized by particularly high hardness and bending strength.

In a preferred embodiment, the body is a tool, further preferably a cutting tool with determined or undetermined cutting edge, wherein the cutting edges are wholly or partially coated with CVD diamond. Particularly preferably, it is a tool having a determined edge such as a disposable insert, a drill bit or mill.

Due to the above described hazardous effect of the binder, it is advantageous, if the latter is reduced in the surface zone or no longer present. Since in the body according to the present invention a large surface of hard materials is available for bonding with the diamond layer, the reduction in cobalt can be smaller than with conventional pretreatments. In one embodiment, the cobalt is essentially only removed up to a depth which is smaller than the mean grain size of the hard materials forming the surface of the substrate, as diagrammatically shown in FIG. 1 (b). This is to ensure that the hard material particles still have good bonding with the substrate. It can thus be advantageously provided that the binder material is removed up to a mean depth which is about 0.1-0.9 times the mean grain size of the hard material particles forming the surface. It is particularly preferable to remove the binder material up to a mean depth which is about half the mean grain size of the hard material particles. Both with respect to the depth of binder removal and with respect to the grain sizes, these are only mean values. The binder of an untreated substrate usually reaches to the surface and can even cover it as a thin film, since mostly there is good wettability of binder and hard material.

In a separate solution to the object according to claim 11, the body according to the present invention may be solely characterized by the binder removal in the surface zone. The body with a substrate of hard metal (consisting primarily of WC and Co) coated with a CVD diamond layer, on at least one of the diamond-coated functional surfaces, has the cobalt contents of the surface (in weight %) reduced in relation to WC by only a maximum of 50%, preferably only a maximum of 25%, particularly preferably only a maximum of 12% with respect to the untreated substrate. This means that with a hard metal having a cobalt content of 10 weight % in the surface zone, for example, a cobalt content of at least 5%, preferably at least 7.5%, particularly preferably at least 8.8% is still present.

It may be possible to determine the depth of the binder removal by metallographic preparations (see diagram of FIG. 1). In the context of the present definition of the invention, however, determination is made by comparing measurements of cobalt on the surface by means of analytical, in particular X-ray graphic methods.

Among these methods, the energy dispersive X-ray fluorescence method (ED-RFA) according to EN ISO 3497 is particularly suitable. The ED-RFA apparatuses are often used for measuring the layer thicknesses of metallic layers, but they also serve for material and alloy analysis. For this purpose, an X-ray beam is directed onto the substrate, and the X-ray fluorescence reflected by the substrate is evaluated in a detector in an energy-dependent manner. The X-ray tube usually works with an accelerating voltage of 30-40 kV. This is how the ratio of Co and WC can be calculated in the surface zone. More accurate values are achieved if the apparatus is calibrated with a series of references with a known composition. For the examples mentioned and in the claims, a voltage of 40 kV was used.

This method has the advantage that it can be directly carried out in the atmosphere and the CVD diamond layers do not influence the measurement. With a measuring spot size of some tenths of mm and more, averaging across the carbides also occurs. Due to the high energy, the X-ray beam penetrates deeply into the surface area of interest, so that information can be derived from a depth of up to approx. 10 μm.

While in the prior art the cobalt on the surface of a WC-Co hard metal with 10 weight % cobalt is etched back to typical values of 0-2 weight %, the cobalt content is only slightly reduced in the method carried out according to the present invention. The method according to the present invention makes it possible for the first time to create strongly adhering layers, although there is only a small reduction in cobalt. If, however, layers are applied using conventional methods with a lack of substrate pretreatment and too little cobalt removed, very poor layer adhesion is the result. These layers flake off by themselves or fail at the slightest stress.

To evaluate adhesion, the Rockwell method and the blast wear test are the usual tests for diamond layers. Adhesion of CVD diamond layers is often determined with a Rockwell impression. To do this, a diamond cone with an aperture angle of 120° and a tip radius of 0.2 mm is pressed onto the layer under a load designated in kilograms. Subsequently the damage around the impression is evaluated. When the adhesion is low, layers will come off easily in the area surrounding the impression due to the high brittleness of the diamond.

This method has a drawback in that the necessary normal force can only be applied with difficulty due to the complex and curved surfaces. Furthermore, the expensive Rockwell diamond is easily damaged, since diamond works against diamond in the test. This is why in the field of CVD diamond layers, a so-called blast wear test is increasingly being used. This involves pressing a sharp SiC in the grain size range of 53-88 μm (no. 180 FEPA standard) in a sand blasting plant by means of pressurized air through a cylindrical nozzle with a diameter of 0.8 mm. The pressure is about 5 bar, the blasting material consumption is about 10 g/min, and the distance to the layer surface is about 6 mm. Subsequently the damage at the center of the impinging jet is evaluated. The test is deemed passed if the substrate has not been exposed at this point.

Both methods are dependent on the layer thickness. Thin layers yield relatively worse results in the abrasive-jet wear test, while with the Rockwell method, thick layers flake off more easily. Layers are contemplated in the range of 2-20 μm, preferably in the range of 4-14 μm.

Coated bodies which due to a lack of pretreatment only have very little cobalt reduction, for example, fail at Rockwell loads of as little as 10 kg or with blast wear values of less than 5 seconds. They are also characterized in that the layers easily flake off under stress or there is a failure within the substrate, before the coating is worn in any discernible manner.

The bodies according to the present invention are particularly suitable as tools, since the high cobalt content of the substrate surface substantially maintains the ductility of the substrate. This is particularly important with thin tools, since they break more easily in operation. Tools are preferred with diameters of less than 3 mm, further preferably less than 1 mm, particularly preferably less than 0.5 mm. In conventional etching, as in the prior art, the surface is made brittle, which reduces bending strength.

In the method according to the present invention, the described recesses of the body according to the present invention are etched by means of a chemical process. Herein, initially at least a portion of the hard material particles forming the surface of the substrate are etched in a transcrystalline manner so that recesses in the form of pits or holes result. In a later step, the substrate is coated with a diamond layer.

In a preferred embodiment, an electrochemical method is applied, wherein the substrate is used as an electrode. Unlike the prior art electrochemical methods, in the present instance the voltage at the electrode is set so high that a potential is reached whereby the above mentioned recesses are formed. Such high potentials are not used in the usual electrochemical etching methods to avoid pitting which, in technology, is otherwise regarded as a negative effect. An operating range above the pitting potential is used, however, for the preferred pretreatment to create a surface which is very advantageous for later layer adhesion.

Preferably an electrochemical method is used wherein the tool is connected as an anode in an etching bath. The cathode is preferably a stainless steel sheet or a container made of stainless steel. Preferably the cathode is at a constant distance from the substrate surface and is matched to the latter. This is why a cylindrical container is particularly suitable for a cylindrical hard metal tool, such as an end milling cutter. A voltage source is usually connected in a voltage-constant manner.

In a particularly preferred embodiment, the method is carried out in such a way that a passivation is achieved. After a high initial current, the current is reduced, depending on the sample geometry and the surface condition, at different rates to a comparatively very small, relatively constant value of less than 10%, for example, of the initial value. Thereby the passivation layer created during the etching process prevents further etch attack.

As has surprisingly been shown, a method using electrochemical, passivating etching treatment with WC-Co hard metals controls itself, so that the Co loss is higher than the WC loss. The ratio of Co to WC is thus smaller after treatment of the surface area of the substrate. In prior pretreatment methods according to the prior art, too much cobalt is usually etched. Complete removal of the cobalt on the surface without fail also leads to a reduction of cobalt in more deeply embedded layers. While the diamond can grow on this surface in an unhindered manner, the surface of the substrate remains porous and brittle. Moreover, bonding of the carbides is weakened to greater depths. The coated body then fails in the interior of the substrate in many cases. In the preferred embodiment of the method according to the present invention, however, the automatic formation of a passivating layer stops cobalt removal.

Sulphuric acid, particularly preferably concentrated sulphuric acid, is used as an electrolyte. It has an excellent passivating effect, small etch pit formation and leads to a minimal etch depth of the cobalt. Other chemicals or mixtures of chemicals may also be used, however, which are able to etch tungsten and cobalt under the above mentioned conditions, in particular acids, such as phosphorous, nitric or hydrochloric acids, preferably in concentrated form. While the latter passivates weakly and results in a higher etch pit density and etching depth, nitric acid, on the other hand, results in quicker passivation and smaller etch depth. The concentrated acids may also be moderately diluted with distilled water. If the dilution is too strong, the result is cobalt etching which is too deep. Other acid mixtures can also lead to similar effects.

When the current has reached its residual value, the passivating layer is preferably stripped in a different bath. An alkaline cleaner, such as diluted caustic-soda solution, is preferably used for this purpose. With the removal of the passivating layer, which consists of the reaction products of the hard materials and the binder, the surface is exposed for a further etch attack. The depth and the diameter of the recesses or holes are further increased thereby.

The process comprising electrochemical etching and removal of the passivating layer is cyclically repeated until the desired surface condition is achieved. The number of cycles required can vary depending on the substrate type and the etch medium. At least one etch cycle is necessary. Usually 2-20 etch cycles are used overall, typically 3-12 cycles.

As the cycles are repeated, the number of recesses or holes is increased, in particular. The structure is ideal when most of the hard materials have one or more holes or recesses. On the other hand, care has to be taken, that the structure is not etched too strongly and the cohesion of the material compound does not suffer too much. It is still permissible, however, that individual carbides are almost completely etched, or that they fall out, when the majority of the carbides forming the surface are held together by the carbide skeleton or the remaining binder. An additional reduction of the mean grain diameter of the carbides is not always deleterious, because this ensures that additional gaps are created for better mechanical gripping between the layer and the substrate. The binder should not be etched away to a depth which is too deep. On the other hand, the reduction of the binder is lessened as the etching cycles are repeated, when the binder has withdrawn behind the surface in the first or the first few cycles. Because of the protrusion of the hard materials and because of the ratio of amounts, the passivating layer is primarily formed by a reaction with the hard material particles.

Voltage values around 25V and initial current densities of about 0.1-0.5 A/cm² were applied with respect to the surface of the immersed substrate. However, this is only a rough indication, since the values depend on the resistance of the electrolyte, the size of the etching bath, the type and size of the counter electrode, the temperature, the form and composition of the substrates, and further framework conditions. Time periods are between 3 and 30 seconds and are easy to determine because of the time-dependent development of the current reduction. Larger substrates usually require longer periods of time. A voltage-constant current source is more practicable for implementation since the formation of the passivation layer can be directly seen from the current reduction.

The method has the further advantage that the etching attack stops itself because of the formation of passivating layers and therefore the reproducibility of the method is considerably improved over and above the prior art. The passivating layers are formed of reaction products during etching and evidently initially stay adhered to the substrate. Overetching by mistake is thereby avoided. The desired etching attack is therefore achieved by cyclically repeating the etching process after removing the passivating layer. This means that measures for inspecting the etching effect are omitted. These are usually necessary since the etching processes are only conditionally reproducible. The reasons herefore lie in variations of the substrate composition due to manufacturing conditions, for example elements, such as carbon, dissolved in the binder. On the other hand, variations arise due to the wear of the chemicals, the concentration of the substrate components dissolved in them and due to the inhomogeneous heating of the substrates in the etching bath.

In the method according to the present invention it is important that only those hard materials which form the surface are etched in a transcrystalline manner otherwise the resulting porosity is too deep, which excessively weakens the substrate surface. This is ensured or supported by the above-mentioned passivating effect.

The passivating layer can also be removed by connecting the substrate in an inverse manner as a cathode (electrolytic stripping). Separate baths or other electrolytes can be used for this purpose. In the most simple case, however, it can be carried out in the same etching bath and in the same electrolyte, by switching the polarity of the current source. For this purpose, an alternating voltage or preferably a bipolar pulsed voltage source can be used so that the etching and passivating steps are carried out without further manual intervention. The passivating layer has been removed to a sufficient extent if after the reestablishment of the original polarity (the substrate as an anode) about the same development of the current is to be observed as during the first iteration of the electrochemical etching. The times, voltage and current values need to be adjusted if necessary. It was observed that a similar current development as with electrolytic etching resulted when the electrolytic stripping was carried out in the proper manner. After a high initial current, the current was also reduced to comparativel very low values. Because of the switch in polarity, the current then flows, however, in the opposite direction. Preferably the electrolytic stripping is carried out in sulphuric acid.

In a preferred variant, the body according to the present invention as described above shows a reduction of the binder material in the area near the surface. The method described ensures both transcrystalline etching of the hard materials according to the present invention and a reduction of the binder in the above described manner. In particular for WC-Co hard metals, the etching rates result in the cobalt always being etched to a slightly greater depth than the hard materials. In other words, cobalt has a more unreactive behavior in acids than tungsten carbide. If in particular embodiments, this behavior is not sufficient, a pure cobalt etching process according to the prior art can be subsequently carried out. Basically the reduction of the binder can be carried out prior to or at the end of the successive processes comprising electrochemical etching and subsequent removal of the passivating layer, preferably, however, during the electrochemical etching itself.

The recesses can additionally be created at the grain boundaries, the edges and the corners. Hereby the grains can also develop a jagged outward appearance. Moreover, pitting can additionally also happen in the binder.

Depending on the execution, an additional general surface reduction and/or reinforced removal on the edges of the carbides can also come about. This is the case, for example, if the pitting potential is not reached during a portion of the etching period. What is crucial is that the transcrystalline etching is faster and the claimed recesses are formed. With an additional surface removal it is possible that recesses and holes are subsequently exposed on the side and thus form open channels and trenches.

As mentioned above, the correct number of etching cycles has to be determined for each substrate type and each etching medium. The person skilled in the art can inspect the etching process with an optical microscope or, even better, with a scanning electron microscope, until the desired surface topography has been achieved. A possibility for inspecting improvements in adhesion is the evaluation with the help of Rockwell indentations and by means of an erosion test (blast wear test). If the layer tears together with the hard metal carbides as a result of stresses caused by the Rockwell indentation, too much cobalt was removed; if the layer flakes off without carbides, there is too much cobalt, or the surface enlargement by transcrystalline etching is not sufficient.

To achieve the desired pitting effect, care has to be taken that the potential of the substrate with respect to its immediate environment is above the pitting potential for a sufficient amount of time without completely passing into the transpassive range. Measuring this potential requires an additional reference electrode and complicated measuring structure and can be carried out only with difficulty under the given circumstances, all the more since the substrate is a multi-component compound material. The necessary electrochemical potential of the substrate, however, is always considerably lower than the voltage between the substrate and the counter electrode mentioned in the examples. Further, the transcrystalline etching does not or only very slightly take place when the forming passivating layer is not removed according to the present invention and the electrochemical etching is repeated.

It is often advantageous to prepare the substrate surfaces prior to the actual etching. They often have different properties even on the same body or tool. It can thus happen that the surfaces are still in the sintered state or affected or damaged by various grinding, polishing or cutting methods. In these cases the affected surfaces can be removed by blasting or other etching methods.

During blasting with abrasive particles, grain sizes are used preferably in the range of a few μm. This method is also referred to as microblasting. This is preferably done with sharp-edged SiC or Al₂O₃ particles having a grain size of less than 100 μm, preferably less than 70 μm, and particularly preferably less than 30 μm. Blasting can basically be carried out in any particular manner. Both centrifugal blasting and pressure blasting are possible, wherein pressure blasting leads to excellent results. Examples of pressure blasting can be pressurized air blasting, wet pressurized air blasting, mud blasting, pressurized liquid blasting and vapor blasting, as they are listed and explained in German DIN standard no. 8200, to which explicit reference is made.

In the preparatory chemical removal of material on the surfaces, the hard materials and the binder can be separately, or preferably jointly, removed.

During the separate removal of the hard material particles, in particular tungsten carbide grains, chemicals may be used which selectively etch WC. Particularly preferably, electrochemical methods with mixtures of alkaline solutions, such as of caustic soda solution, caustic potash solution and/or sodium carbonate, are used, as described, for example, in the WO 97/07264 publication.

For separate etching of the binder, basically all acids may be used, which etch the binder, in particular cobalt. HNO₃, and preferably mixtures of H₂SO₄/H₂O₂, HCl/H₂O₂ and HCl/HNO₃, may be used for etching. Electrochemical etching methods with direct or alternating current are particularly preferred. Diluted solutions of HCl or H₂SO₄ are preferred herein.

In a variant of the present invention, for preparation, binder etching is initially carried out, followed by hard material etching. This usually increases the roughness of the substrate, since the hard material etchant can penetrate more deeply into the substrate. This greater roughness which also increases the roughness of the coated body, is disadvantageous for certain applications, on the other hand, adhesion can be further improved. A preparatory treatment of this type is described, for example, in WO 2004/031437.

Such preparatory method steps are suitable, in particular, when the hard material surface is damaged by the manufacturing process (for example by rough grinding treatment) or when the chemical composition is changed, for example by the sintering process. If the surface of the substrate is to be changed as little as possible to maintain, for example, the edge sharpness with cutting tools, such preparatory method steps are less suitable. The method is then less expensive and the surface roughness remains less pronounced. This may mean that the parameters need to be adjusted, as described above.

Optionally a mild pretreatment with diamond powder can be carried out prior to diamond coating to increase the nucleation density, also referred to as prenucleation or seeding. This is usually not necessary, however, since there is a sufficient number of nucleation points due to the great number of edges on the carbides. Preferably this seeding is carried out in an emulsion with diamond powder in an ultrasonic bath.

It is recommended to carry out cleaning of the substrate between the individual method steps, such as by rinsing with distilled water and ultrasonic cleaning in ethanol. This particularly applies after delivery of the substrates, prior to the chemical treatment according to the present invention and prior to the diamond coating. Between the electrochemical etching step and subsequent removal of the passivating layer, cleaning is not absolutely necessary. After extended use, however, this can lead to cross-contamination with chemicals and therefore to changes in the chemical composition.

Preferably coating is done by means of a CVD method. Herein, diamond grows on the created surface. Due to the method described and the particular structure of the carbides of the pretreated substrate, there is excellent gripping between the diamond layer and the substrate. The layer thickness can vary in a wide range from 0.1-100 μm, preferably 1-40, further preferably 4-20 μm. With tools and components with complex geometries, the hot filament method has proven particularly suitable.

Doped, micro and nano-crystalline layers can be deposited, as well as multilayers herefrom. Further, additional metallic and ceramic functional layers can be applied.

Finally it may be noted that the described method is by no means the only one which can create the described transcrystalline recesses. Other methods, such as spray etching, etch processes in other chemicals, electrochemically supported or not, and etching processes in melts, hot gasses or plasmas are also possible.

Embodiments of the invention will be described in the following with reference to the drawings in more detail, wherein:

FIG. 1 is a schematic representation of a cross sectional view of a body vertical to a substrate surface (a) in an untreated state, (b) after pretreatment, and (c) after coating;

FIG. 2 shows photographs of optical-microscopic images after a different number of etching cycles;

FIG. 3 shows a photograph of an SEM microscopic image of a conventionally pretreated substrate surface after exposing the carbides;

FIG. 4 is a photograph of an SEM microscopic image of a substrate surface pretreated with a method according to one embodiment of the invention after exposing the carbides, and

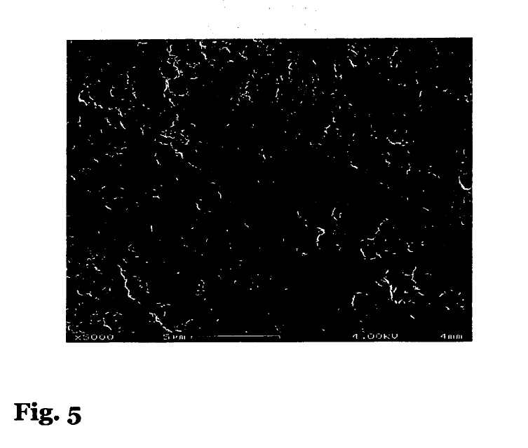

FIG. 5 shows a photograph of an SEM image of a substrate surface pretreated according to an embodiment of the invention without exposing the carbides.

FIG. 1 shows a body in a schematic representation of a cross section vertical to the substrate surface or diamond layer 4. Only a few hard material particles 1 are shown in an exemplary manner. The proportion of binder phase 2 is shown in an exaggerated manner. Binder phase 2 envelopes hard materials 1 usually as a narrow layer. Specifically with carbides, hard material particles 1 can touch and possibly bond with one another to create a so-called carbide skeleton.

On the left in FIG. 1, (a) initially shows the untreated substrate. (b) shows the same portion after carrying out an etching method as described above, in which recesses 3 are formed. Finally, (c) shows the same portion after carrying out a diamond coating process.

The method described above uses successive cycles comprising an etching step and removing the passivating layer. FIG. 2 shows the surface of a substrate after varying numbers of cycles have been carried out. Above (a) shows the surface after the first cycle, in which grinding marks are still visible. Moreover, individual etching indentations are also shown. (b) still shows grinding marks after 3 cycles, and there are still coherent areas without etching indentations. Finally, after 10 cycles, as shown under (c), grinding marks are no longer visible. The surface has been completely changed by etching indentations.

FIG. 3 shows a conventionally pretreated substrate surface of a WC-Co hard metal, as it can be achieved with a method according to WO 97/07264. Here parts of the surface have been removed, by completely removing WC particles. Further, the cobalt has been etched. The hard materials have kept their original idiomorphous form. The surface is optically hardly distinguishable from a hard metal surface created by a break, or a sinter material surface of an untreated hard metal substrate.

In contrast, FIG. 4 shows a substrate surface of a WC-Co hard metal as it is aimed at by the present invention. The substrate shows strong transcrystalline etching on the surface. The transcrystalline etching is particularly pronounced here, since the carbides had previously been exposed as in FIG. 3 with a preliminary conventional etching step, before, in a further step, a transcrystalline etching was carried out. Almost each carbide grain shows a plurality of recesses in the form of holes. In some places it can be seen that grains have been completely perforated, so that channels result.

FIG. 5 shows a substrate surface of a WC-Co hard metal which was subjected only to the transcrystalline etching step without a previous conventional pretreatment. Compared with FIG. 4, carbides were not exposed here, only the ground surface can be seen. The individual carbides are hardly discernible in such a view; only the recesses can be seen.

A number of application examples will be explained in the following.

### EXAMPLE 1

An end milling cutter of hard metal with a functional diameter of 6 mm is to be coated with a diamond layer. The tool material (substrate) is an extra fine grain variety with WC grains in the range of 0.5-0.8 μm and a cobalt binder with 6 weight %. To block grain growth during sintering, chromium carbide was used, which is contained at about 0.3 weight %.

Prior to diamond coating, the substrate was pretreated as follows: after cleaning off oil residues, the functional area of the tool is subjected in a preparatory manner to a mechanical pretreatment (microblasting with hard material particles). After a cleaning step to remove the blasting medium, the actual chemical pretreatment is carried out:

The etching bath consists of a cylindrical stainless steel container of about 15 cm in diameter. The blasted functional area of the tool is immersed in concentrated sulphuric acid. Herein, the tool is connected as an anode and the stainless steel container as a cathode. 25 volt are applied between the anode and the cathode in a voltage-constant manner. Immediately after immersion, a passivating layer begins to form which is closed to such an extent after 10 seconds that there is almost no further etch attack. This can be seen from an initially high current flow of about 6 A, which quickly falls after formation of the passivating layer to very low values of about 0.05 A.

After this etching step, the functional area is briefly immersed in an alkaline cleaning solution of 10% NaOH. Herein, the passivating layers consisting of the reaction products of the hard metal components, are stripped off. By suitable surface analysis methods, for example, with the above mentioned ED-RFA method, it can be shown that removal of the cobalt was slightly greater than that of the WC.

To ensure particularly good adhesion of the diamond coating, in the present example, the electrochemical etching with subsequent removal of the passivating layer is repeated 10 more times. Herein, primarily the number of recesses and holes is increased. The latter have been uniformly distributed over the tool surface, similar to the manner shown in FIG. 2. Scanning-microscopic images show that almost all WC grains of the tool surface have one or more of these characteristic holes. At a grain size of 0.8 μm, the mean hole size is 0.05-0.1 μm. The cobalt phase has been almost completely removed near the surface.

Subsequently, the sample is cleaned and seeded and provided with a nano-crystalline diamond layer 9 μm thick. During seeding, diamond crystals can accumulate in the holes.

In the coating process, growth of the diamond layer on the WC surface enlarged by the holes and recesses occurs, further, due to the undercuts, there is excellent mechanical gripping between the layer and the substrate.

The cobalt percentage measured as described above by the ED-RFA method prior to and after diamond coating was 5.5 weight %.

### EXAMPLE 2

In the present example, the same substrate as in the first example was coated with the same diamond layer, however, subjected to a slightly modified pretreatment according to the present invention. Instead of the blasting treatment, a preparatory electrochemical etching is carried out according to the principle of WO 97/07264. The treatment duration of the preparatory electrochemical etching in 10% NaOH solution at a current of about 1 A is about 60 seconds. The aim is to substantially expose the surface of the WC carbides. The subsequent electrochemical etching in concentrated sulphuric acid, as in example 1, was now able to attack more effectively, so that only 2 cycles needed to be carried out. In this case, seeding was also omitted.

The cobalt content measured by means of the ED-RFA method prior to and after diamond coating was 5.5 weight %. The blast wear test reached 76 seconds.

### Comparative Example

The same substrates were initially pretreated, as in example 2, according to the principle of WO 97/07264. According to the teaching of this publication, the cobalt was reduced, however, at the end by a conventional acid etch. None of the samples reached the blast wear value of example 2. The best value was 60 seconds. This however, required a cobalt reduction to 1.2 weight %. Samples in which the cobalt value on the surface was more than 4 weight % (all measurements by means of ED-RFA) already flaked off in the coating plant during cooling, or after a blasting period of less than 5 seconds.

### EXAMPLE 3

A drill for processing printed circuit boards (PCBs) with a functional diameter of 0.3 mm of a WC-Co hard metal with 10% cobalt and a mean WC grain size of 0.6 μm is electrochemically etched in 3 cycles. As in example 1, a cycle consists of an electrochemical etching with concentrated sulphuric acid and subsequent electrochemical removal of the passivating layer. Due to the smaller surface, lower currents are used here. In the present removal step, the polarity is only switched, i.e. the substrate is briefly connected as a cathode, until the current has fallen. At the end of the 3 cycles, the substrate is cleaned in an NaOH solution again. The tools subsequently only have very little cobalt depletion, further, the characteristic transcrystalline grain etching has taken place. After a cleaning step, the tool is coated with a multilayer of nano-crystalline and microcrystalline diamond layers; the layer has a thickness of 9 μm and consists of a sequence of 3 double layers each having a microcrystalline and a nano-crystalline layer.

As shown by the measurement using the ED-RFA method across the layer, the cobalt content was only reduced to 9.0 weight %.

### EXAMPLE 4

A milling tool for MMC treatment with a functional diameter of 12 mm consists of an extra fine grain variety with a Co content of 10 weight %. The rest consists of WC with further admixtures below 0.5 weight %. A pretreatment is carried out in a preparatory manner according to WO 2004/031437 to roughen the fine grain substrate. For this purpose the functional area is etched in nitric acid, resulting in a Co-free porous zone. The etching depth of the cobalt is about 2 μm. By electrochemical removal of the WC in an NaOH solution the porous zone created by the first step is removed, and the result is a surface with increased roughness. The tool is subsequently electrochemically treated as in example 2, but only 2 treatment cycles need be carried out due to the preparatory etching. Corresponding to the larger surface, higher currents result here. After a cleaning step, again in an NaOH solution, and a seeding step, the tool is coated with an 8 μm thick nano-crystalline diamond layer.

The ED-RFA measurement showed a reduction of the Co content to 9.1 weight %.

1-33. (canceled)

34. A body with a substrate of cemented carbide or cermet, said substrate consisting of hard material particles and binder material and an adhering diamond layer applied on top of it, characterized in that at least a portion of said hard material particles at the surface of the substrate and below the diamond layer have transcrystalline recesses in the form of holes.

35. The body according to claim 34, characterized in that the percentage of hard material particles with at least one recess is at least 10%,

36. The body according to claim 35, characterized in that the percentage of hard material particles with at least one recess is at least 25%.

37. The body according to claim 36, characterized in that the percentage of hard material particles with at least one recess is at least 50%.

38. The body according to claim 34, characterized in that a percentage of the surface of the recesses is at least 1% of the surface of the substrate, wherein said percentage results from a parallel projection of the recesses into a plane of observation parallel to the substrate surface.

39. The body according to claim 34, characterized in that a percentage of the surface of the recesses is at least 5% of the surface of the substrate, wherein said percentage results from a parallel projection of the recesses into a plane of observation parallel to the substrate surface.

40. The body according to claim 34, characterized in that a percentage of the surface of the recesses is at least 10% of the surface of the substrate, wherein said percentage results from a parallel projection of the recesses into a plane of observation parallel to the substrate surface.

41. The body according to claim 35, characterized in that a ratio of a mean depth of the recesses in the hard material particles having at least one recess to the mean diameter of the hard material particles is at least 0.1.

42. The body according to claim 41, characterized in that said ratio is at least 0.2.

43. The body according to claim 41, characterized in that said ratio is at least 0.3.

44. The body according to claim 34, characterized in that a ratio of a mean depth of the recesses in the hard material particles having at least one recess to the mean diameter of the recess is at least 0.5.

45. The body according to claim 44, characterized in that said ratio is at least 1.0.

46. The body according to claim 45, characterized in that said ratio is at least 1.5.

47. The body according to claim 34, characterized in that the individual recesses completely perforate the hard material particles, so that in a hard material particle there are channels open on both sides.

48. The body according to claim 34, characterized in that the binder material is partially removed in the surface zone of the substrate.

49. The body according claim 48, characterized in that the binder material is removed up to a mean depth which is 0.1 to 0.9 times a mean grain size of the hard material particles forming the surface.

50. A body with a substrate of hard material consisting primarily of WC and Co with functional surfaces coated with a CVD diamond layer, characterized in that, on at least one of the diamond-coated functional surfaces, the cobalt content of the surface in weight % relative to WC, each measured by means of energy-dispersive X-ray fluorescence, is only reduced by at most 50% or less with respect to the untreated substrate, where the diamond layer has an adhesion better than Rockwell 10 kg or the diamond layer withstands the blast wear test for at least 5 seconds.

51. A body according to claim 50, where said cobalt content is only reduced by at most 25% or less with respect to the untreated substrate.

52. A body according to claim 50, where said cobalt content is only reduced by at most 12% or less with respect to the untreated substrate.

53. The body according to claim 50, characterized in that the thickness of the diamond layer is 1-40 μm.

54. The body according to claim 53, characterized in that the thickness of the diamond layer is 2-20 μm.

55. The body according to claim 53, characterized in that the thickness of the diamond layer is 4-14 μm.

56. The body according to claim 50, characterized in that the diamond layer consists of a plurality of layers, wherein at least one of said layers is primarily of nano-crystalline diamond.

57. The body according to claim 50, characterized in that the body is a tool.

58. The body according to claim 57, characterized in that the body is a tool with at least one cutting edge, which is also wholly or partially provided with a diamond layer.

59. The body according to claim 50, characterized in that the substrate in the non-surface-treated zone contains 7-20 weight %, binder.

60. The body according to claim 59, characterized in that the substrate in the non-surface-treated zone contains 7-12 weight % binder.

61. The body according to claim 34, characterized in that the hard material particles of the substrate are primarily tungsten carbide (WC) and the binder material (2) is primarily cobalt (Co), so that other elements or compounds are present in an amount of less than 30 weight %.

62. The body according to claim 61, characterized in that other elements or compounds are present in an amount of less than 5 weight %.

63. The body according to claim 62, characterized in that other elements or compounds are present in an amount of less than 2 weight %.

64. A method for pretreating and coating a substrate material with a diamond layer, wherein the substrate material comprises hard material particles and surrounding binder material, wherein initially at least a portion of the hard material particles forming the surface of the substrate is surface etched by chemical means in a transcrystalline manner in such a way that recesses result in the form of indentations or holes, and in a later step the substrate is coated with a diamond layer.

65. The electrochemical method according to claim 64, wherein the substrate functions as an electrode and is connected to a voltage source via a counter electrode, wherein the substrate is held at a positive potential with respect to the counter electrode during all or most of the electrochemical treatment duration.

66. The method according to claim 64, wherein the etching process consists of one or a plurality of etching steps, which each stop after a certain time by the formation of passivating layers, or their etching rate is considerably lowered.

67. The method according to claim 66, wherein the passivating layer is chemically removed in a respective further process step.

68. The method according to claim 67, wherein the passivating layer is removed by means of an electrochemical method, wherein the substrate functions as an electrode and is connected to a voltage source via a counter electrode, wherein the substrate is held at a negative potential with respect to the counter electrode during all or most of the electrochemical treatment duration.

69. The method according to claim 66, wherein the operation comprising the electrochemical etching and the subsequent removal of the passivating layer is successively repeated, until the desired structure and etching depth is reached.

70. The method according claim 64, wherein the etching medium consists of acids, preferably of concentrated sulphuric acid.

71. The method according to claim 64, wherein prior to etching or at the end of the successive operations comprising etching and subsequent removal of the passivating layer, or during the etching itself, a portion of the binder is removed.

72. The method according to claim 64, wherein for preparing the substrate prior to said etching a mechanical removal of part of the surface of the substrate by means of blasting treatment, preferably by a microblasting treatment, particularly preferably by a microblasting treatment with SiC, is carried out.

73. The method according to claim 64, wherein for preparing the substrate prior to said etching, a chemical removal of part of the surface of the substrate is carried out.

74. The method according to claim 73, wherein the preparatory chemical removal is carried out by means of an electrolytic method in an alkaline solution, wherein the substrate is primarily connected as an anode.

75. The method according to claim 64, wherein, after the etching operations and prior to the diamond coating, a mechanical pretreatment with diamond powder is carried out to increase the nucleation density for the growing diamond layer.

76. The method according to claim 64, wherein between the individual process steps, in particular prior to diamond coating, one or more cleaning steps are carried out.
